(19) United States
(12) Patent Application Publication
(10) Pub. No.: US 2003/0184314 A1
(43) Pub. Date: Oct. 2, 2003

(54) Apparatus and method of providing output voltage

(76) Inventor: Ilan Barak, Kfar Saba (IL)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/105,922

(22) Filed: Mar. 26, 2002

(51) Int. Cl. G01R 27/26

(52) U.S. Cl. 324/658

(57) ABSTRACT

Briefly, in accordance with one embodiment of the invention, a power supply having switched capacitor array and a memory comprising a connection scheme is provided. The connection scheme may comprise data of interconnections of at least some selectable capacitors of the switched capacitor array to set an output voltage of the power supply. The output voltage of the power supply may be a division ratio between the number of columns to the number of rows of the switched capacitor array.

### BACKGROUND

Voltage regulation of power from a direct current (DC) voltage source, such as, for example, a battery, may be accomplished via the use of a serial regulator. A serial regulator may waste power in proportion to the voltage drop across it. Furthermore, the voltage drop across a serial regulator may result in an efficiency loss.

To overcome the efficiency loss of a serial regulator, a switching regulator may be used, if desired. An example of a switching regulator may be a charge pump regulator. A charge pump regulator may provide a regulated voltage by utilizing the charging and discharging characteristics of capacitors. However, the output voltage level may be a fraction of an input voltage.

Thus, there is a continuing need for better ways to provide a voltage regulator to mitigate the above described disadvantages.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a block diagram of an embodiment of a power supply in accordance with an embodiment the present invention;

FIG. 2 is a schematic representation of a switched capacitor array that may be used in accordance with an embodiment of the present invention; and

FIG. 3 is a schematic representation of a switched capacitor array in accordance with an alternative embodiment of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention. Furthermore, the term “plurality” may be used throughout the specification to describe two or more components, devices, elements, parameters and the like. For example, the phrase “plurality of capacitors” describes two or more capacitors, the phrase “plurality of switches” describes two or more switches and the like.

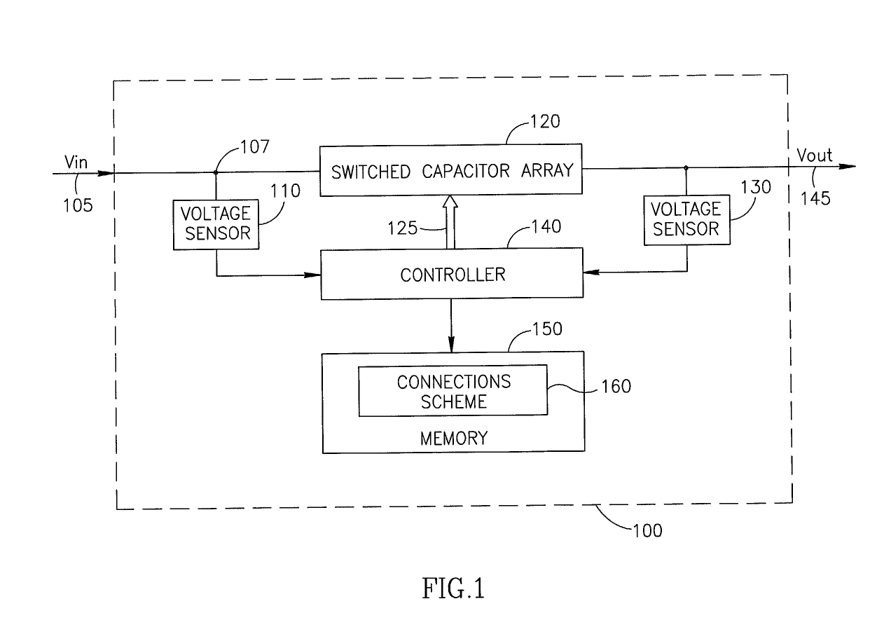

Turning first to FIG. 1, a block diagram of a power supply 100 according to an embodiment of the present invention is shown. It should be understood that the embodiment described below is an example only. Furthermore, in alternative embodiments of the present invention other components, additional components, or a different arrangement of components may be used.

Power supply 100 may include a voltage sensor 110, a switched capacitor array 120, a voltage sensor 130, a controller 140 and a memory 150 that may store information or data such as connection schemes of at least some selectable capacitors in switched capacitor array 120, for example connection scheme 160.

Although the scope of the present invention is not limited in this respect, embodiments of the present invention such as, for example, power supply 100, may be used in a variety of electronic devices. Non-limiting examples of such electronic devices include mobile communication devices, base stations, mobile computers, desktop computers, computers accessories, wireless and wireline network devices, Personal Digital Assistant (PDA) devices, Personal Computing Assistance devices, toys, and the like.

Although the scope of the present invention is not limited to this example, operation of power supply 100 may be as follows. Voltage sensor 110 may measure an input voltage 105 (Vin), for example by sampling with a resistor (not shown) the current of an input line 107. Voltage sensor 110 may further include for example an analog to digital converter (ADC) (not shown). The ADC may convert the current of input line 107 to digital data bits. Voltage sensor 110 may input the measurements to controller 140. Although the scope of the present invention is not limited in this respect, controller 140, may be a micro processor, a digital signal processor, a Reduced Instruction Set Computer (RISC) processor, an 8 bit or more controller, a costume gate array, registers, multiplexers and the like. Controller 140 may calculate, based on the measurements, variation of an output voltage 145 (Vout). For example, controller 140 may use equation 1 to calculate the variation of Vout 145.

$$Equation 1 : \\ V out = V in \frac{{Column}_{n}}{{Row}_{n}} ; wherein$$

Vout—may be the target output voltage;

Vin—may be the input voltage;

Columnₙ—may be the number of columns; and

Rowₙ—may be the number of rows.

Assuming that power supply 100 target output voltage Vout is 6 volts, the input voltage Vin is 15 volts, the number of columns of the switched capacitor array 120 is 2 and the number of rows is 5. If the input voltage drops to 10 volts, the output voltage will drop to 4 volts and the variation in the output voltage will be 2 volts. According to the variation, controller 140 may translate, for example, the variation of Vin 105 to an address of memory 150 (for example for a variation of 2 volts the address may be 200) and may download connection scheme 160 according to the address. For example, the connection scheme that is downloaded from address 200 may include data that provides a division ratio between rows and columns that may fix the variation in the output voltage. Thus, by downloading connection schemes with different division ratios, controller 140 may regulate the output voltage.

Although the scope of the present invention is not limited in this respect, connection schemes may include data of interconnections of at least some of the selectable capacitors of the switched capacitor array 120. The interconnections of selectable capacitors may be done by switches. Furthermore, the data in connections scheme may indicate which of the plurality of the selectable capacitors may be selected. Furthermore, the data may indicate a ratio between the number of rows to the number columns of the switched capacitor array 120. For example, the data of connection scheme 160 may be arranged as data bits, set of instructions of a computer program, control signals and the like. The computer program may instruct controller 140 to set the switches to charge and to discharge a plurality of selected capacitors of the switched capacitor array 120 in a certain fashion. In another example, connection scheme 160 may provide control bits to control lines 125 of controller 140. Control lines 125 may be operably coupled to switches in switched capacitor array 120. For example, bit “1” may close a switch and bit “0” may open the switch. However, it should be understood that connection scheme 160 may be represented in many different ways. For example, the data of the connection scheme may represent the addresses of switches of switched capacitor array 120. Furthermore, in alternative embodiments of the present invention, memory 150 may be a set of switches and connection scheme 160 may provide the value of the switches to a programmable counter (not shown). For example, the programmable counter may have direct control of the switches in switched capacitor array 120.

Although, the scope of the present invention is in no way limited in this respect, data stored in connection scheme 160 may indicate to controller 140 to set the switches to connect a plurality of selectable capacitors in switched capacitor array 120. The interconnection of the capacitors may set the output voltage. For example, Vout 145 may be related to a division ratio between the number of rows to the number of columns of switched capacitor array 120. The division ratio may be a rational number that includes non-integer numbers and integer numbers. Controller 140 may regulate Vout 145 by downloading different connection schemes information of different division ratios.

Although the scope of the present invention is not limited in this respect, in alternative embodiments of the present invention voltage sensor 130 may measure output voltage 145, for example by sensing the current of an output line 135, and may provide the measurements to controller 140. According to the output voltage measurements, controller 140 may download from memory 150 a connection scheme that may provide data to regulate output voltage 145 to a target voltage level, if desired. For example, controller 140 may regulate output voltage 145 by downloading from memory 150 connection schemes that may provide data to set the voltage level of output voltage 145 according to variations of input voltage 105 and according to variations of output voltage 145.

Although the scope of the present invention is not limited in this respect, memories that may be used with the present invention such as, for example memory 150, may be nonvolatile memories such as, for example, a read only memory (ROM), a Flash memory, a programmable ROM (PROM), an erasable PROM (EPROM), an electrical EPROM (E²PROM) and the like, and volatile memories such as, for example, a read access memory (RAM), dynamic RAM (DRAM), static RAM (SRAM), flip-flops, registers, buffers, set of switches and the like.

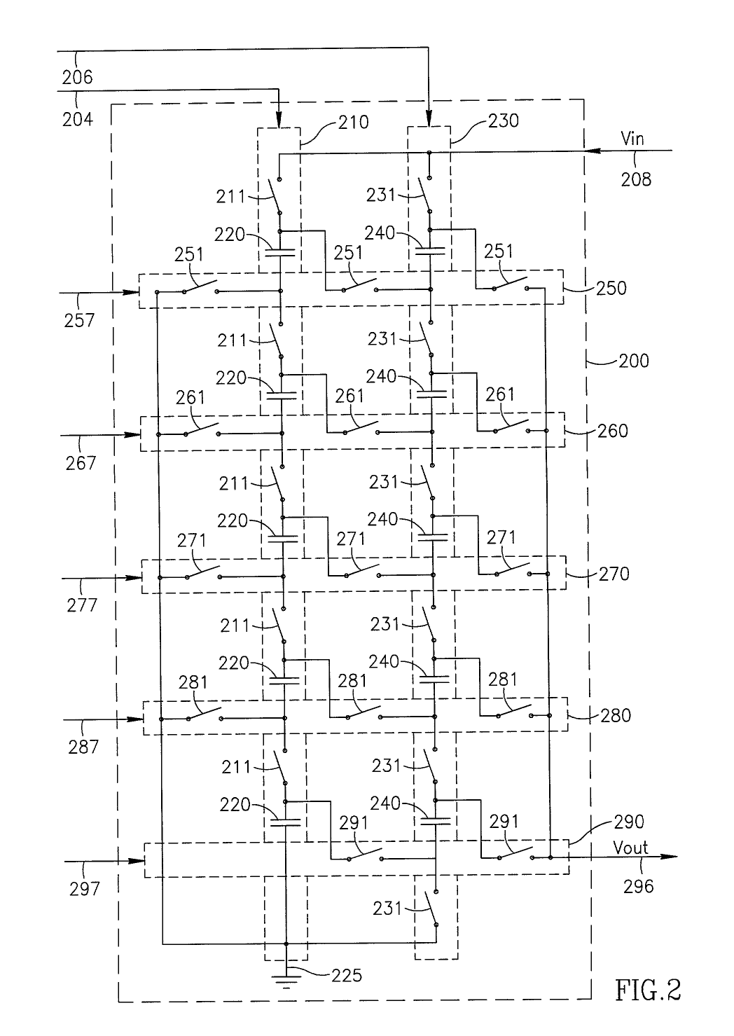

Turning now to FIG. 2, a detailed description of an embodiment of a switched capacitor array, generally referenced 200, will be described. Although the scope of the present invention is not limited to this example, a switched capacitor array 200 may include columns 210, 230 and rows 250, 260, 270, 280 and 290. Column 210 may include switches 211 and capacitors 220. Column 230 may include switches 231 and capacitors 240. The capacitors that are arranged in columns may be arranged in rows by opening the switches in the columns and closing the switches in the rows. Rows 250, 260, 270, 180, 290 may include switches to discharge capacitors. For example, row 250 may include switches 251, row 260 may include switches 261, row 270 may include switches 271, row 280 may include switches 281 and row 290 may include switches 291.

Although the scope of the present invention is not limited in this respect, control lines 204 and 206 may be used to charge the capacitors arranged in columns 210 and 230, respectively. Control lines 257, 267, 277, 287, 297 may be used to discharge the capacitors arranged in rows 250, 260, 270, 280 and 290, respectively. Charging and discharging the selected capacitors may be done by controlling the switches of switched capacitor array 200.

Although the scope of the present invention is not limited in this respect, when switches 211 are closed, capacitors 220 may be charged. As is shown in FIG. 2, switches 211 may connect input voltage 208 (Vin) and a ground potential 225 to charge capacitors 220 of column 210.

Although the scope of the present invention is not limited in this respect, the capacitors arranged in column 230 may be charged by closing the switches of column 230 in the same fashion that was described above with the respect of charging the capacitors that are arranged in column 210.

Although the scope of the present invention is not limited in this respect, discharging the selectable capacitors of switched capacitor array 200 may be done by opening the switches in columns 210 and 230 and closing the switches in rows 250, 260, 270, 280 and 290. Hence, arranging the charged capacitors in rows to provide Vout 296 to a load (not shown).

An example of discharging capacitors 220 and 240 by switches 251, of row 250 will now be described. Switches 251 may interconnect capacitors 220 and 240. Switch 251 may connect capacitor 220 to a ground potential 225 and switch 251 may connect capacitor 240 to an output voltage 296. A load (not shown) may be connected to output voltage 296 to discharge capacitors 220 and 240.

Although the scope of the present invention is not limited in this respect, discharging the selectable capacitors of switched capacitor array 200 may be done by closing the switches of rows 250, 260, 270, 280, 290 in the same fashion that was described above with respect of discharging the selectable capacitors by the switches of row 250.

For simplicity, it should be understood to one skilled in the art that switches in rows may interconnect selected capacitors of switched capacitor array 200 to provide output voltage 296. In addition, the switches in columns may charge the selected capacitors of switched capacitor array 200 by connecting the selected capacitors arranged as column to Vin 208 and to ground potential 225. Thus, this operation may charge the selected capacitors that are arranged in columns 210, 230 to a voltage level that may be substantially equal to the input voltage level.

It will be appreciated that some embodiments of the present invention may comprise switches not all of the same type. For example, switches that may be included with embodiments of the present invention may be transistors, switched diodes, multiplexers, mechanical switches and the like.

Although the present invention is not limited to this example, controller 140 or other control components may control the control line of switched capacitor array 200 according to the data that may be provided by connection scheme 160. Furthermore, output voltage level 296 may be generated by alternately charging and discharging the selectable capacitors. In addition, charging and discharging the selectable capacitors may be accomplished by alternately closing the switches of the columns where the switches of the rows are open, and alternately closing the switches of the rows where the switches of the columns are open. The charge and discharge rate may be dependent on the capacitance of the capacitors of the switched capacitor array 200. The capacitance of a capacitor of the switched capacitor array 200 may have substantially equal capacitance as other capacitors of switched capacitor array 200. However, in other embodiments of the present invention the switches of the switched capacitor array 200 may be controlled independently disregarding the arrangement of rows and columns.

An example of calculating the output voltage of some of the embodiments of the present invention may be provided by equation 1 that was described above. However, in alternative embodiments of the present invention, Vout may be provided by equation 2.

$$Equation 2 : \\ V out = V in \frac{{CapCo1}_{n}}{{CapRow}_{n}} ; wherein$$

Vout—may be output voltage 296;

Vin—may be the voltage of the capacitors when they are substantially fully charged;

CapColₙ—may be the number of capacitors in a column; and

CapRowₙ—may be the number of capacitors in a row.

Furthermore, the capacitance of a capacitor arranged in a column may have a substantially equal capacitance to a capacitor arranged in a row. For example, with the use of equation 1, the output voltage of switched capacitor array 200 (having two columns and five rows) may be, for Vin of 6 volts, 2.4 volts. It will be appreciated that other predefined output voltages may be achieved with a switched capacitor array having different number of rows and columns from the switched capacitor array that was described above. However, in some embodiments of the present invention, connection scheme 160 may control the output voltage by setting the division ratio between the number of rows and the number of columns of the switched capacitor array.

Although the scope of the present invention is not limited in this respect, in alternative embodiments of the present invention, the output voltage may be set by setting the division ratio between the number of capacitors in a row and the number of the capacitor in a column of the switched capacitor array 200. In addition, in other alternative embodiment of the present invention, the capacitors that are arranged in rows may be charged and the capacitors that are arranged in columns may be discharged. In those embodiments, the output voltage level may be calculate by equation 3:

$$Equation 3 : \\ V out = V in \frac{{Row}_{n}}{{Column}_{n}} ;$$

or by equation 4:

$$Equation 4 : \\ V out = V in \frac{{CapRow1}_{n}}{{CapCo1}_{n}} .$$

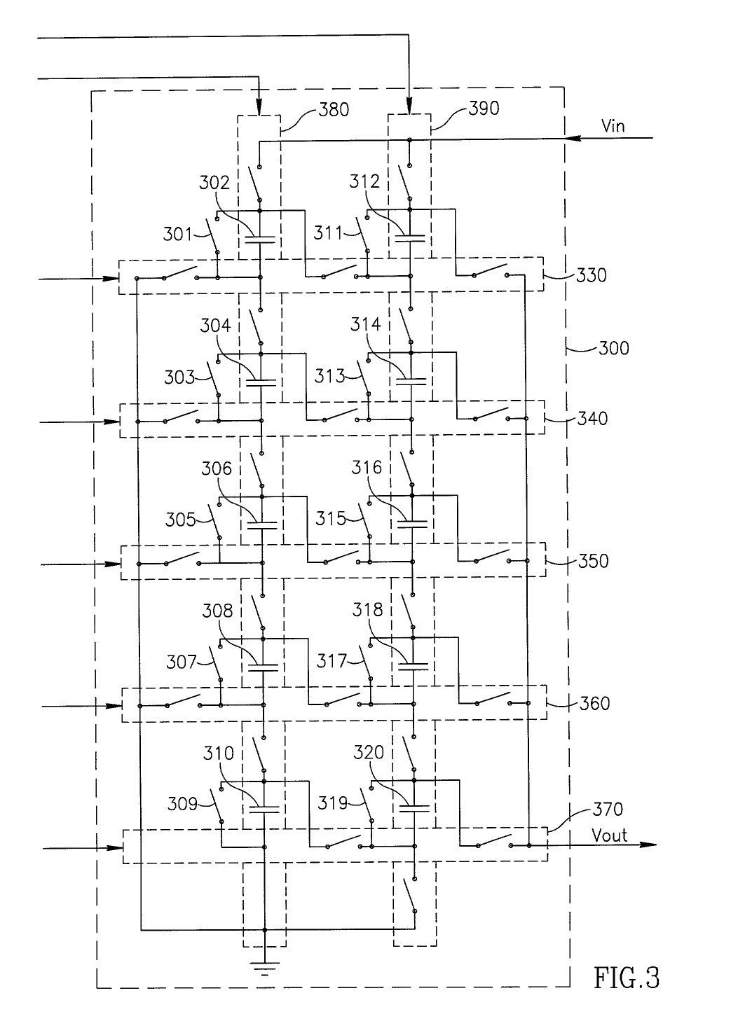

Turning now to FIG. 3, an alternative embodiment of a switched capacitor array, generally referenced 300 will be described.

Although the scope of the present invention is not limited in this respect, the difference between switched capacitor array 200 of FIG. 2 and switched capacitor array 300 is that switched capacitor array 300 further includes bypass switches generally referenced 301, 303, 305, 307, 309, 311, 313, 315, 317, 319. Bypass switches 301, 303, 305, 307, 309, 311, 313, 315, 317, 319 may bypass capacitors 302, 304, 306, 308, 310, 312, 314, 316, 318, 320 respectively. Bypass switches 301, 303, 305, 307, 309, 311, 313, 315, 317, 319 may be used to set the number of rows and the number of columns of switched capacitor array 300 by bypassing capacitors arranged in rows and by bypassing capacitors arranged in columns. Thus, setting the output voltage level of the switched capacitor array 300 may be done by providing a connection scheme that includes data that may comprise the number of rows, the number of columns and a division ratio between the number of rows to the number of columns or a division ratio between the number of columns to the number of rows. For example, switches 301, 303, 305, 307, 309 may bypass capacitors 302, 304, 306, 308, 310 of column 380 and switches 311, 313, 315, 317, 319 may bypass capacitors 312, 314, 316, 318, 320 of column 390. Furthermore, to reduce the number of rows, for example, from five to four, switches 309, 319 may bypass capacitors 310, 320 respectively, if desired. In addition, to reduce the number of columns from two to one, switches 301, 303, 305, 307, 309 may bypass capacitors 302, 304, 306, 308, 310, if desired.

Although the scope of the present invention is not limited in this respect, a target output voltage level may be achieved by providing connection schemes that may set the output voltage level. The connection schemes may set the number of columns and the number of rows to provide a division ratio that set the output voltage level to be a substantially equal to the target voltage level, accordingly. Furthermore, switched capacitor array 300 may include any number of rows and columns. The desired number of rows and columns may be set with data provided by the connection schemes.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

What is claimed is:

1. An apparatus comprising:
a switched capacitor array comprising a plurality of selectable capacitors, wherein at least some of the selectable capacitors may be coupled together to provide an output voltage level; and
a memory to store data, the data indicating which of the plurality of capacitors are selectable.

2. The apparatus of claim 1, wherein the switched capacitor array comprises:
switches to interconnect the selected capacitors to be charged according to the data provided by a connection scheme; and
switches to interconnect the selected capacitors to be discharged according to the data provided by the connection scheme.

3. The apparatus of claim 2, wherein the selected capacitors of the switched capacitor array have substantially equal capacitance.

4. The apparatus of claim 2, wherein the data indicates a ratio between the number of rows to the number of columns of the switched capacitor array.

5. The apparatus of claim 2, wherein the switched capacitor array further comprises:
a switch to bypass a capacitor of the switched capacitor array.

6. An apparatus comprising:
a first voltage sensor to measure an input voltage level;
a switched capacitor array to regulate an output voltage level according to the input voltage level; and
a Flash memory to store a connection scheme comprising data of interconnections of selectable capacitors of the switched capacitor array, wherein the data indicates a ratio between the number of rows to the number of columns of the switched capacitor array.

7. The apparatus of claim 6, further comprising:
a controller to control switches of the switched capacitor array to charge and to discharge capacitors according to the data provided by the connection scheme.

8. The apparatus of claim 7, further comprising:
a second voltage sensor to measure the output voltage level, wherein the controller is adapted to adjust the output voltage according to measurements of the input voltage and the output voltage.

9. The apparatus of claim 6, wherein the switched capacitor array comprises:
switches to interconnect a plurality of selected capacitors in columns; and
switches to interconnect a plurality of selected capacitor in rows,
wherein the selected capacitors in the columns are to be charged and the selected capacitors in the rows are to be discharged.

10. The apparatus of claim 6, wherein the switched capacitor array comprises:
switches to interconnect a plurality of selected capacitors in columns; and
switches to interconnect a plurality of selected capacitor in rows,
wherein the selected capacitors in the rows are to be charged and the selected capacitors in the columns are to be discharged.

11. The apparatus of claim 8 wherein the switched capacitor array further comprises:
a switch to bypass a capacitor of the switched capacitor array.

12. An apparatus comprising:
a switched capacitor array to provide an output voltage so that a division ratio between an input voltage to the output voltage is a non integer rational number.

13. The apparatus of claim 12, wherein the switched capacitor array comprises:
a plurality of selectable capacitors;
switches to interconnect at least some of the selectable capacitors to be charged according to data provided by a connection scheme; and
switches to interconnect at least some of the selectable capacitors to be discharged according to the data provided by the connection scheme.

14. The apparatus of claim 13, further comprising:
a controller to alternate the switches to charge and discharge at least some of the selectable capacitors according to the connection scheme.

15. The apparatus of claim 13, wherein the capacitors have substantially equal capacitance.

16. A method comprising:
regulating an output voltage level of a switched capacitor array by interconnecting capacitors of the switched capacitor array in rows and columns according to variations of an input voltage level.

17. The method of claim 16, further comprising:
providing connection schemes of interconnections of the capacitors according to the variations.

18. The method of claim 16, further comprising:
selecting a connection scheme having data indicating a division ratio between the number of capacitors arranged in columns to the number of capacitors arranged in rows.

19. The method of claim 16, further comprising:
selecting a connection scheme having data indicating a division ratio between the number of capacitors arranged in the rows to the number of capacitors arranged in the columns.

20. The method of claim 18, further comprising:
charging the capacitors arranged in the columns and discharging the capacitors arranged in the rows.

21. The method of claim 19, further comprising:
charging the capacitors arranged in the rows and discharging the capacitors arranged in the columns.

22. The method of claim 16, further comprising:
bypassing a capacitor of the switched capacitor array.

23. The method of claim 16, wherein interconnecting further comprises:
interconnecting the capacitors in the row and the columns according to a division ratio of the output voltage level to the input voltage level that is a non integer rational number.
